(19) United States
(12) Patent Application Publication
(10) Pub. No.: US 2003/0222672 A1
(43) Pub. Date: Dec. 4, 2003

(54) Testing optical displays

(76) Inventor: Paul Winer, Santa Clara, CA (US)

Correspondence Address: Timothy N. Trop, TROP, PRUNER & HU, P.C., 8554 KATY FWY, STE 100, HOUSTON, TX, 77024-1841, US

(21) Appl. No.: 10/161,350

(22) Filed: May 31, 2002

(51) Int. Cl. G01R 31/00

(52) U.S. Cl. 324/770

(57) ABSTRACT

By measuring the quiescent current of optical display elements, such as liquid crystal on silicon optical displays, an automated test may be implemented to determine device functionality. As a result, the costs associated with conventional optical or machine vision testing may be substantially reduced.

### BACKGROUND

This invention relates generally to optical displays and to techniques for testing optical displays.

A variety of optical displays exist for displaying information in association with processor-based systems. For example, liquid crystal on silicon (LCOS) or micromirror-based displays may be utilized to display information generated by processor-based or other systems.

Optical displays may exhibit a variety of internal faults that can cause high quiescent current states. Examples of such internal faults include bridging and stuck at faults, often the result of an electrical defect that creates an unwanted conducting path or short. In other words, the optical displays may exhibit high quiescent currents at times when low quiescent currents would be expected.

As a result of these high quiescent currents, the characteristics of the display may be degraded. Thus, it would be desirable to locate these faults in a cost effective fashion.

Especially in large optical displays, including those that have on the order of over a million individual optical modules or pixels, even a few faults may affect the overall quality of the display. Typically, these faults are verified by human visual inspection. Thus, these techniques may be slow and costly. Machine vision techniques may be applied on fully assembled devices when either pixel defects cannot be tolerated or when displays are of lower pixel counts. Often pixels have a response time of greater than 10 milliseconds. Thus, machine vision techniques may be time consuming and relatively expensive.

Thus, there is a need for better ways to test optical displays.

### BRIEF DESCRIPTION OF THE DRAWINGS

FIG. 1 is a schematic depiction of one embodiment of the present invention;

FIG. 2 is a hypothetical graph of current versus time for an optical display that passes a test in accordance with one embodiment of the present invention;

FIG. 3 is a hypothetical graph of current versus time for a device that fails a test in accordance with one embodiment of the present invention; and

FIG. 4 is a block depiction of a portion of a display that has failed a test in accordance with one embodiment of the present invention.

### DETAILED DESCRIPTION

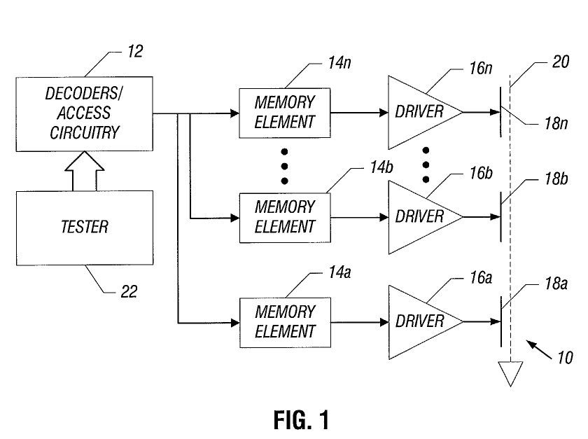

Referring to FIG. 1, in accordance with one embodiment of the present invention an optical display 10 may be in the form of a liquid crystal on silicon (LCOS) optical modulator. However, embodiments of the present invention may be applicable to a wide variety of other optical displays including silicon micromirror displays. The display 10 may have a closely coupled integrated circuit and optical modulator whose properties may include the ability to function in a static manner, requiring relatively small operating currents when compared to currents induced when abnormal shorting of the modulators occurs.

Referring again to FIG. 1, the display 10 may include a transparent electrode 20, which may be formed on a glass substrate, that is typically grounded, in close proximity to a reflective electrode array 18 on the metal stack of an integrated circuit coupled to drive electronics. Between the electrode 20 and the integrated circuit represented by the electrodes 18, is a layer of liquid crystal which is a dielectric. The optical modulator, therefore, presents itself as a capacitive load to the drive electronics.

Under normal conditions, once a driver 16 has charged or discharged the effective capacitance, the driver 16 draws no additional current. If the circuitry on the integrated circuit were fully static, there would be no current flow except for transistor leakage currents when the display 10 is no longer clocked and its inputs remain fixed. If, however, the driven electrode 18 were shorted to a node of opposite polarity, such as an adjacent pixel, the driver 16 may continue to sink or source current. This is detectable at the device power supply as increased quiescent current.

Thus, a tester 22 may include current measuring circuits and may also control or drive the decoders and/or access circuitry 12 of the optical display 10. The decoders/access circuitry 12 may drive a plurality of memory elements 14a through 14n. Each memory element 14, in turn, drives a driver 16a through 16n. Each driver 16 is coupled to a reflective electrode 18a through 18n in one embodiment. A pixel is defined between each electrode 18 and the transparent electrode 20.

The tester 22 operates the display 10 in a manner to potentially activate a short condition between pixels at each electrode 18. In two dimensional displays 10, a checkerboard pattern and its inverse may be sufficient to locate most shorts. Additional patterns may be used to further isolate faulty pixels to faulty rows, columns, quadrants, or individual pixels. Special patterns specific to unique topographies or routings may require additional patterns to activate potential shorts.

The tester 22 may be an external tester in one embodiment or the tester 22 may be an internal or built-in self-test (BIST) circuit in another embodiment.

The tester 22 measures the power supply current after sufficient time has elapsed and the display 10 supply current has reached a steady state. The measured current is statistically compared to measured currents in known good displays to determine if the current measured in the device under test was excessive. Excessive currents are indicative of a detected fault.

The current draw of the display 10 may also be measured indirectly by a voltage droop in some embodiments. With this approach, after the display 10 has reached the steady state, the power supply may be disconnected. The internal capacitance of the display 10 discharges at a characteristic rate depending on whether the display 10 is faulty. This discharge may be measured as a voltage at the power supply input to the display 10.

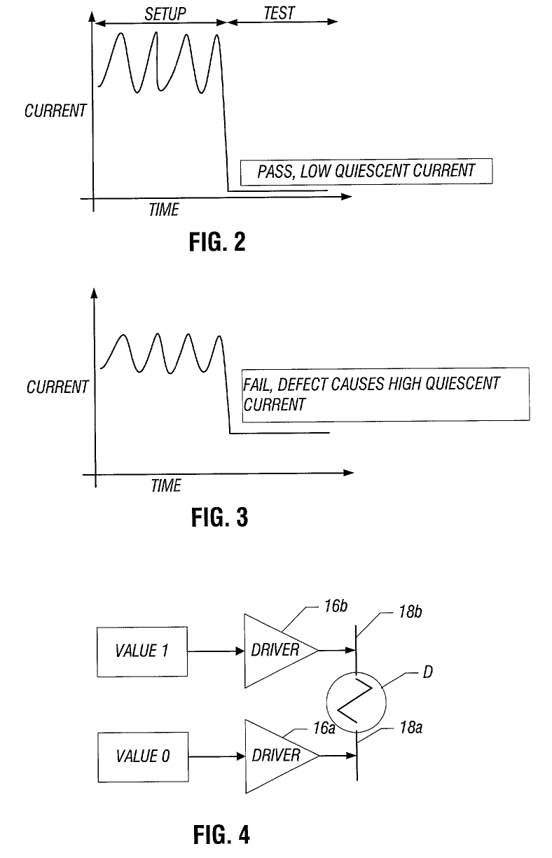

Referring to FIG. 2, in accordance with one embodiment of the present invention, the tester 22 may automatically drive each electrode 18 through a set-up period and then into a test period. In the test period, the display electrode passes if low quiescent current is detected. However, as shown in FIG. 3, if higher quiescent current is detected during the test period, the display 10 may be considered to have a fault or defect, as indicated in FIG. 3.

Thus, as shown in FIG. 4, a value one, of the checkerboard pattern of alternating one and zero values, may be driven on one electrode 18b and a value zero may be driven on an adjacent electrode 18a. If there is a short, as indicated at D, excessive quiescent current may be detected.

Thus, in accordance with some embodiments of the present invention, an electrical test may be implemented in an automated fashion. No human or machine vision testing may be required in some cases. As a result of its automated nature, the test may be run rapidly and is limited only by the settling time of the display electronics, not the response time of the optical modulator. A simple test pattern, such as the checkerboard and its inverse, may be utilized. The test pattern may check all the pixels for shorts. In some embodiments the test may not require full assembly of the display 10. The test may be accomplished at wafer sort, as one example. The test may also be done after the display 10 is fully assembled. In addition, in some embodiments, the techniques described herein may increase overall test coverage. Additionally, the quiescent test vectors may be implemented to find display electronics failures unrelated to the optical modulator in some cases.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
measuring the quiescent current of an optical display; and
comparing said quiescent current to a reference.

2. The method of claim 1 wherein comparing said quiescent current includes comparing the measured quiescent current to a reference current representative of the quiescent current of a substantially fault-free display.

3. The method of claim 1 including automatically driving the display to automatically test the elements of the display.

4. The method of claim 1 including measuring the quiescent current by measuring the voltage droop.

5. The method of claim 1 including driving said display through a test pattern.

6. The method of claim 5 including driving said display in a checkerboard pattern.

7. The method of claim 1 including detecting a short between adjacent elements.

8. The method of claim 1 including measuring the quiescent current of a liquid crystal over silicon display.

9. The method of claim 1 including using an external tester to measure the quiescent current of an optical display.

10. The method of claim 1 including incorporating a test circuit in an optical display for measuring the quiescent current of the optical display.

11. The method of claim 1 including testing the display before final assembly.

12. The method of claim 1 including testing the display after final assembly.

13. A tester for an optical display comprising:
a circuit to measure the quiescent current of an optical display; and
a device to compare said measured quiescent current to a reference.

14. The tester of claim 13 wherein said device compares the measured quiescent current to a reference current representative of the quiescent current of a substantially fault-free display.

15. The tester of claim 13 wherein said device automatically drives the display to automatically test the elements of said display.

16. The tester of claim 13 wherein said circuit measures the voltage droop.

17. The tester of claim 13 wherein said device drives said display through a test pattern.

18. The tester of claim 17 wherein said device drives said display in checkerboard pattern.

19. The tester of claim 13 wherein said device detects a short between adjacent display elements.

20. The tester of claim 13 wherein said tester is external to said display.

21. The tester of claim 13 wherein said tester is part of a display.

22. The tester of claim 21 including a liquid crystal on silicon display.

23. An optical display comprising:
a plurality of optical display elements;
a circuit to measure the quiescent current of said elements; and
a device to compare said measured quiescent current to a reference.

24. The display of claim 23 wherein said device compares the measured quiescent current to a current representative to the quiescent current of a substantially fault-free display.

25. The display of claim 23 wherein said device automatically drives the display elements to automatically test said elements.

26. The display of claim 23 wherein said circuit measures voltage droop.

27. The display of claim 23 wherein said device drives said display elements through a test pattern.

28. The display of claim 27 wherein said device drives said display elements in a checkerboard pattern.

29. The display of claim 23 wherein said device detects a short between adjacent display elements.

30. The display of claim 23 wherein said display elements are liquid crystal on silicon display elements.
